(19) United States
(12) Patent Application Publication
(10) Pub. No.: US 2004/0238950 A1
(43) Pub. Date: Dec. 2, 2004

(54) Tunable low loss transmission lines

(75) Inventor: My The Doan, Singapore (SG)

Correspondence Address: STEPHEN B. ACKERMAN, 28 DAVIS AVENUE, POUGHKEEPSIE, NY, 12603, US

(73) Assignee: Agency For Science, Technology And Research

(21) Appl. No.: 10/449,967

(22) Filed: May 30, 2003

(51) Int. Cl. H01L 29/00

(52) U.S. Cl. 257/734

(57) ABSTRACT

This circuit and method provides for tunable, low loss, high frequency transmission line behavior with optimum attenuation loss and characteristic impedance. The advantage of this circuit and method includes the ability to modify the geometry of the slots or absence of metal over the lossy silicon substrate and the geometry of the main conductor. By simply including the slots in the ground plane(s) during the design/mask layout (independent of IC lithography), we can change the inductance L, resistance R, transconductance G, and capacitance C of the transmission line. With the flexibility to change the L, R, G, and C values of the distributed network model of the integrated circuit transmission line, the characteristic impedance Zc and the attenuation loss can be manipulated without changing linewidth, thickness of the metal lines and/or the thickness of the dielectric layer, which require complex integrated circuit fabrication process technology development.

### BACKGROUND OF THE INVENTION

1. Field of the Invention

The present invention generally relates to the general field of high frequency operation of integrated circuits and the transmission line properties of these circuits. More particularly, this invention relates to a circuit and a method for providing tunable low loss transmission line behavior in integrated circuits. The low loss, high frequency behavior is measured via attenuation loss and characteristic impedance.

2. Description of the Prior Art

The prior art includes several techniques on using SiGe/Si, silicon germanium/silicon technology in the millimeter-wave applications, such as 10 and 40 Gbit/s data communication integrated circuits and 26-28 GHz broadband wireless integrated circuits. Commercially, 10 Gbit/s data communication integrated circuits using SiGe are available and are replacing III-V compound (i.e. gallium arsenide) based integrated circuits. However, silicon is lossy and all signal lines operating beyond 1 GHz become transmission lines. The important figures of merit for transmission lines are characteristic impedance, attenuation loss, and phase loss.

FIG. 1 shows a prior art of an inductor with patterned ground shield 110, which is used to reduce the eddy current in the silicon substrate. A drawback to the use of the patterned ground shield is the increased amount of substrate coupling capacitance. This increased coupling capacitance results in lower resonance frequency or lower characteristic impedance.

FIG. 2a shows a cross-sectional view of a prior art standard conducting strip over a lossy silicon substrate. FIG. 2a shows a prior art cross-sectional diagram of a transmission line. The metal conductor 240 is shown. Also the substrate 230 is made up of lossy silicon. A magnetic field [symbol] 4210 loops around the metal conductor 240. An electric field [symbol] 220 emanates from the main conductor 240 and terminates in the lossy silicon, Si 230.

FIG. 2b shows a cross-sectional view of a prior art standard conducting strip 241 over a metal layer 222. This metal layer 222 is overlaid on top of a lossy silicon substrate 231. This metal layer 222 is used as a ground plane. This ground plane can connect to the silicon substrate through contacts 251. Layer 227 is the insulator between metal layers and between metal and silicon substrate. A magnetic field 211 loops around the metal conductor 241. The metal layer 222 would prevent eddy currents in the silicon substrate. An electric field E 221 emanates from the main conductor 241 and terminates at the metal layer 222. The width of metal layer 222 can be optimized to ensure as much of the [symbol] and [symbol] fields to terminate on it.

FIG. 3 shows four graphs 310. These graphs are based on prior art transmission lines. Graph 310 is a curve of attenuation vs. width of transmission line at a frequency equal to 20 GHz. Graph 311 is a curve of characteristic impedance vs. width of transmission line at a frequency of 10 GHz. Graph 312 is a curve of characteristic impedance vs. width of transmission line frequency of 20 GHz. Graph 313 is a curve of attenuation vs. width of transmission line at a frequency equal to 10 GHz.

All four of the graphs have a negative slope, decreasing as the width of the transmission line conductor increases. Comparing curves 310 and 313 shows that attenuation is greater at higher frequencies. Comparing curves 311 and 312 shows that characteristic impedance is greater at lower frequencies.

U.S. Pat. No. 6,211,056 B1 (Begley, et al.) “Integrated Circuit Air Bridge Structures and Methods of Fabricating Same” describes various novel techniques of fabricating integrated circuit devices with air bridges. These devices result in lower capacitances during high frequency operation.

U.S. Pat. No. 6,362,525 B1 (Rahim) “Circuit Structure Including a Passive Element Formed Within a Grid Array Substrate and Method for Making the Same” describes a circuit structure that combines an integrated circuit with a passive circuit element formed within a grid-array substrate. The invention shows a transmission line and ground plane over a lossy substrate. This invention also describes the fabrication techniques for said circuit structure.

U.S. Pat. No. 6,150,197 (Boles) “Method of Fabricating Heterolithic Microwave Integrated Circuits” describes a process for fabricating Heterolithic microwave integrated circuits. The structure described is a transmission line and ground plane over a lossy substrate with pedestals.

U.S. Pat. No. 6,258,688 B1 (Tsai) “Method to Form a High Q Inductor” describes a process for fabricating a high Q inductor utilizing trenches and implants into the substrate. A technique utilizing STI (Shallow Trench Isolation) is described.

### SUMMARY OF THE INVENTION

It is therefore an object of the present invention to provide a circuit and a method for providing a tunable low loss transmission line behavior in integrated circuits. It is further an object of this invention to provide a circuit and a method for providing low loss, high frequency transmission line behavior with optimum attenuation loss and characteristic impedance.

The objects of this invention are achieved by a low loss and tunable transmission line made up of a transmission line and a metal ground plane with slots cut out of the metal. The metal ground plane with slots sits on top of the lossy silicon substrate separated by a dielectric layer. The metal ground plane and the ground of the silicon substrate are connected through a contact and vias. While “metal ground plane” is often used here, its meaning covers all conducting ground planes, i.e. polysilicon, aluminum, copper, or gold. For optimal condition, this electrical conductor carries an electrical signal in a direction perpendicular to the slot cutouts. The slot cutouts are parallel with the direction of a magnetic field. At the slot cutouts magnetic fields and electric fields, which are generated from time varying signals carried through the transmission line, looping through said silicon substrate. Whereas, at other areas, the [symbol] fields and the [symbol] fields would terminate at said metal ground plane. Using the telegraphic model, the transmission lines behave as inductor, resistor, transconductor, and capacitor networks when operating at high frequency. The transmission line has a characteristic impedance, which is a function of the inductance, resistance, transconductance and capacitance of the network segments. The transmission line has an attenuation loss, which is a function of the inductance, resistance, transconductance and capacitance of the network segments. Having the slot cutouts, in the ground plane, the inductance, capacitance and transconductance in the networks would be changed due to modifications of the [symbol] and [symbol] fields. This, in turn, changes the characteristic impedance and attenuation loss. The number of slots, the geometries of the slots, and the placement of the slots can be designed to tune the characteristic impedance and attenuation loss according to specifications.

The above and other objects, features and advantages of the present invention will be better understood from the following detailed description taken in conjunction with the accompanying drawings.

### BRIEF DESCRIPTION OF THE DRAWINGS

FIG. 1 shows a prior art patterned ground shield structure.

FIG. 2a shows a prior art cross section of a standard transmission strip line over a lossy silicon substrate.

FIG. 2b shows a prior art cross section of a transmission strip line with a metal ground plane.

FIG. 3 shows a prior art graph of characteristic impedance and attenuation versus transmission strip width.

FIG. 4a shows the transmission line structure which is the main embodiment of this invention.

FIG. 4b shows a cross sectional view through one of the cut out slots of the main embodiment structure of this invention.

FIG. 4c shows a cross sectional view through an area where there is no cut out slot in the main embodiment structure of this invention.

FIG. 5 shows a distributed circuit model of the transmission line structure of this invention.

FIG. 6a shows an experimental plot of characteristic impedance versus signal frequency for 3 different structures including the structure of this invention.

FIG. 6b shows an experimental plot of attenuation versus signal frequency for 3 different structures including the structure of this invention.

FIG. 7a shows a 3-dimensional view of the invention with a transmission line (731) with slots (761) and ground plane (741) which is above the transmission line.

FIG. 7b shows a 3-dimensional view of the invention with a transmission line (732) between two slots (762 and 782) and two ground planes (742 and 772).

FIG. 8 shows a 3-dimensional view of a fourth embodiment of the invention which has two symmetric transmission lines chips connected with a super via packaging technique.

FIG. 9 shows a top view of the invention which can use different shaped slots instead of regular perpendicular slots.

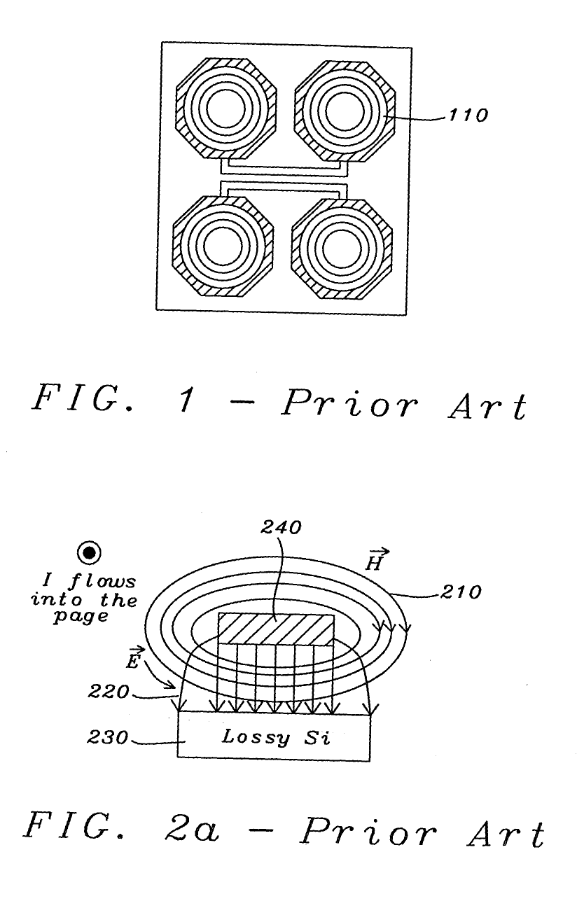

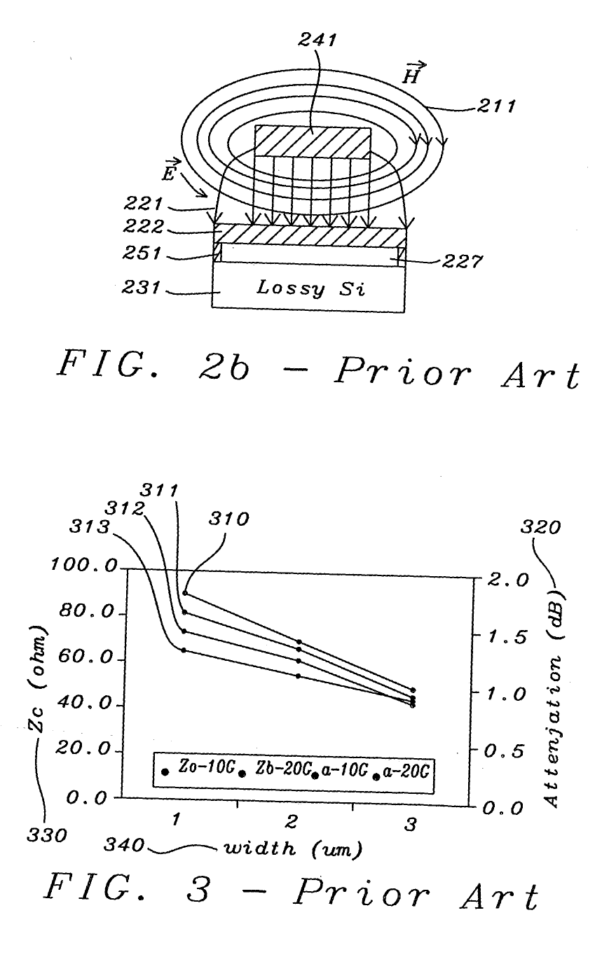

### DESCRIPTION OF THE PREFERRED EMBODIMENT

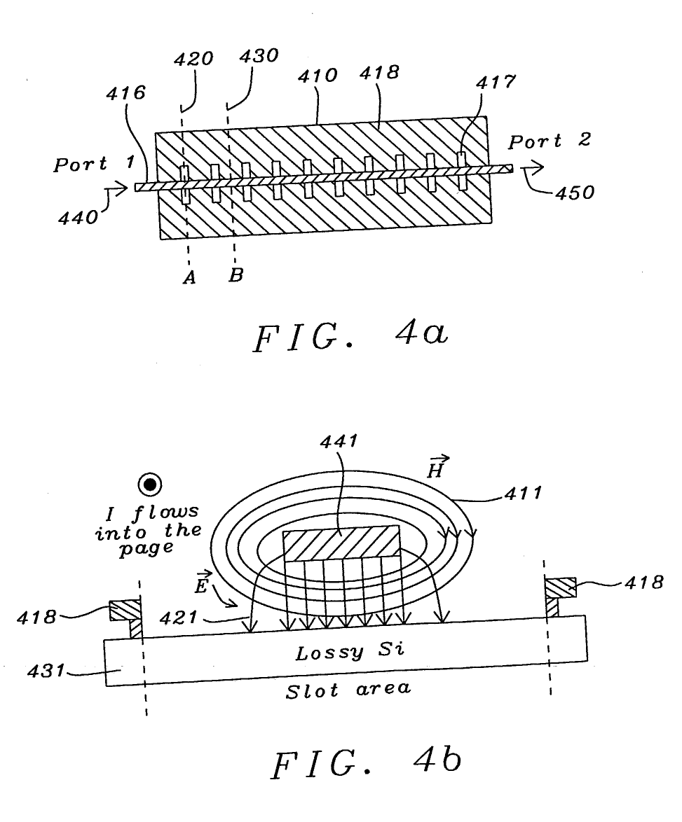

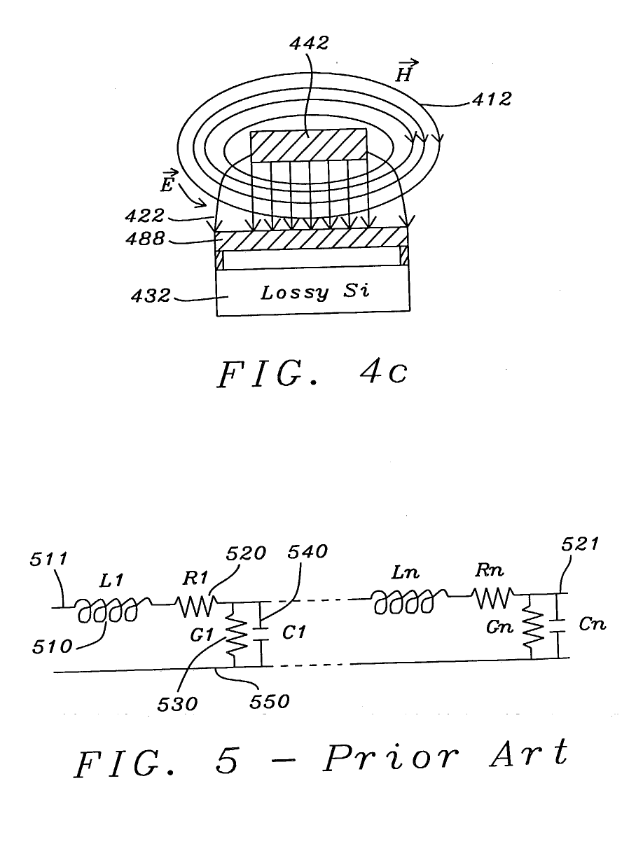

FIG. 4a shows the main embodiment of this invention. There is a silicon substrate 410, which is overlaid by a layer of metal 488 as shown in FIG. 4c. The layer of metal is represented by cross-hatching 418 in FIG. 4a. FIG. 4a shows slot openings or absence of metal 417. The electrical signal conductor 416 is shown in FIG. 4a. Port 1 440 or the input to the transmission is shown in FIG. 4a. Port 2 450 or the output of the transmission line is also shown in FIG. 4a. There are two cross-sections shown in FIG. 4a. Cross-section A is drawn through one of the slots 420. The slot represents an absence of metal over the silicon substrate. Cross-section B 430 is drawn through a section of the transmission line where there is no slot. Where there is no slot, there is metal over the silicon substrate.

FIG. 4b shows the cross-sectional view of the cross-sectional cut at A 420 in FIG. 4a. FIG. 4b shows magnetic fields represented by [symbol] and electric fields represented by [symbol] . The electrical conductor 416 of FIG. 4a is shown as 441 in FIG. 4b. The silicon substrate 410 of FIG. 4a is shown as 431 in FIG. 4b. The magnetic fields 411 in FIG. 4b are elliptical and loop around the electrical conductor 441. Eddy current would be induced in the silicon substrate. The electrical field lines 421 go from the electrical conductor 441 to the lossy silicon substrate 431. Where there is no slot, there is metal over the silicon substrate.

FIG. 4c shows the cross-sectional view of the cross-sectional cut at B430 in FIG. 4a. FIG. 4c shows magnetic fields represented by [symbol] and electric fields represented by [symbol] . The electrical conductor 416 of FIG. 4a is shown as 442 in FIG. 4c. The silicon substrate 410 of FIG. 4a is shown as 432 in FIG. 4c. The magnetic fields 412 in FIG. 4c are elliptical and loop around the electrical conductor 442. No eddy current in the silicon substrate would be induced. The electrical field lines 422 go from the electrical conductor 442 to the metal ground plane 448. Since the electric fields 422 ends up on the metal 488, there is less energy loss where there are no slots. In FIG. 4b, the electric field lines terminate in the lossy silicon. This occurs where there are slots 417 in the metal over the silicon substrate as shown in FIG. 4a.

Magnetic and electric field lines are infinite. In the description, we describe the local magnetic and electric fields because we deal with a finite size of ground planes in these situations.

The key to this invention is the distributed slots or openings in the metal ground plane overlaid over the silicon substrate as shown in FIG. 4a. The slots allow designers to get the best characteristic in attenuation loss and characteristic impedance of both cases shown in FIGS. 4b and 4c. Recall the termination of electric fields on a metal plate reduces attenuation loss at high frequency. This means there is no loss due to eddy current induced in the silicon substrate. But the Zc, characteristic impedance is also lower due to higher capacitance coupling between the signal line and ground planes. On the other hand, with silicon as ground plane, attenuation loss is lower at low frequency, but increases rapidly at high frequency. Having slots in the ground plane, low attenuation loss in both the low and high frequency region can be achieved. In addition, characteristic impedance would be constant throughout different frequency ranges. Similarly, the presence of the slots or openings in the metal layer reduces the area of the parallel plate parasitic capacitance caused by the metal (488) over the silicon substrate.

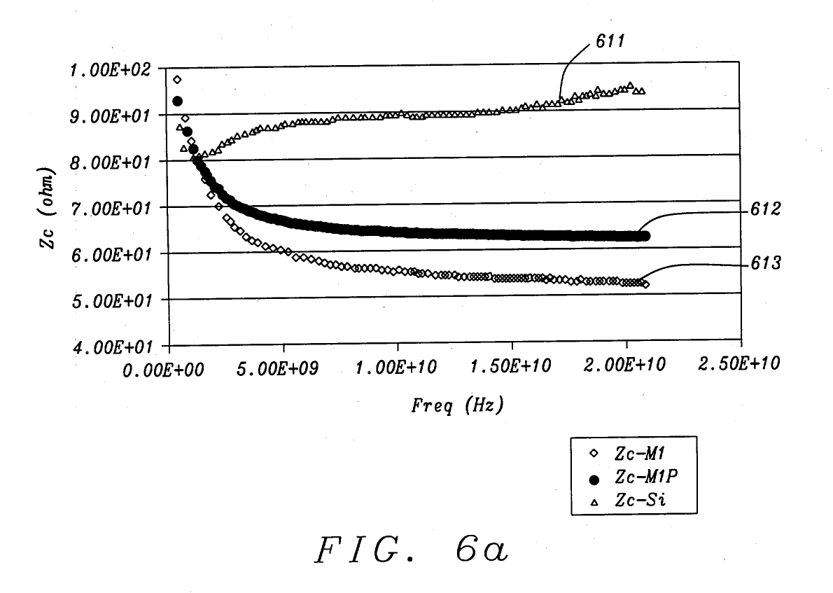

FIG. 5 shows a circuit model of the transmission line, which results at frequencies above 1 GHz. The transmission line is represented by ‘n’ segments, each of which are modeled with an inductor, Ln, a resistor, Rn, a transconductance, Gn and a capacitance, Cn. The first segment in FIG. 5 contains an inductor, L1 whose one node is connected to the transmission line input 511, and whose other node is connected to a node of a resistor, R1. The other node of resistor, R1 is connected to nodes of transconductance G1 and capacitor C1.

The other node of the transconductance G1 (530) is connected to a common return node 550. Also, the other node of the capacitor c1 is connected to the common return node 550. The L, R, G, C segment described above is repeated in order to model various lengths of transmission lines. The output node 54 of the transmission line is shown in FIG. 5. The final segment of the transmission line circuit model in FIG. 5 labels the circuit elements as Ln, Rn, Gn, and Cn to illustrate the repeatability of the L, R, G, C segments.

Referring to FIG. 5, the formulas for the two key transmission line parameters are listed below.

The characteristic impedance of the transmission line is given as Zc =square root of [(R+jwL)/(G+jwc)] where R equals the total transmission line inductance, G equals the total transmission line transconductance, C equals the total transmission line capacitance and w equals the frequency of operation.

The attenuation loss of the transmission line is given as gamma=a+jb=[square root of (R+jwL)] ×(G+jwC) where a=attenuation loss. Manipulating R, L, C and G in order to manipulate characteristic impedance, Zc, and attenuation, α, can be done by the use of ground shields.

The use of ground shields reduces the attenuation loss at high frequency at the expense of reducing the characteristic impedance. With high-speed IC applications such as Mux, Demux, impedance matching is very important. Without impedance matching, matching loss can be high, or in the extreme case, oscillations could result.

Characteristic impedance can be manipulated by changing the width of the transmission lines as seen by the graph of FIG. 3. But this will affect the density of ICs. Also, more importantly, it is not possible to obtain high impedance and lower attenuation loss at the same time.

In addition, the characteristic impedance can be manipulated by changing the thickness of metal films and of the dielectrics. However, this requires process technology development.

This invention with slots in ground planes can change L, C, G and R and therefore manipulate the characteristic impedance and the attenuation loss without changing line width (effecting IC density) and thickness of metal lines and/or dielectric thickness (effecting process technology).

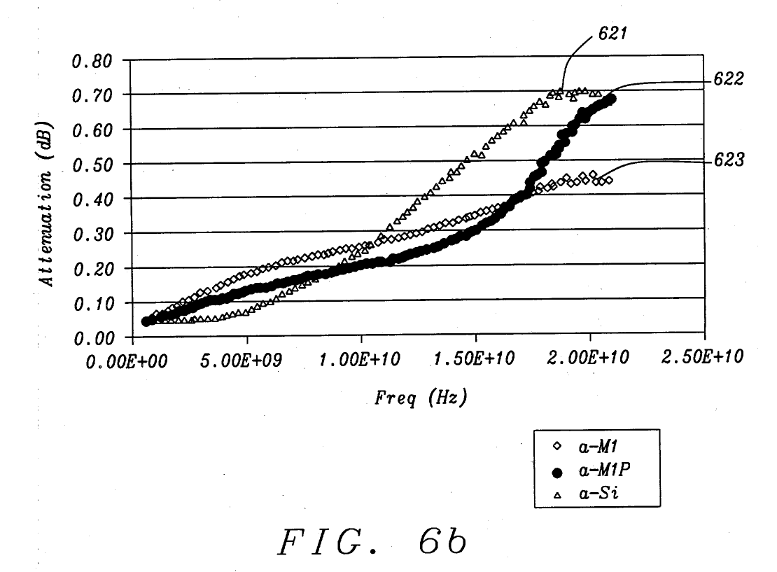

FIGS. 6a and 6b show graphs of measured results. FIG. 6a shows a plot of characteristic impedance vs. frequency. Curve 611 shows the highest characteristic impedance, but with frequency dependence at high frequency (>56 GHz) which results with no metal ground plane over the lossy silicon substrate. Curve 613 shows the lowest characteristic impedance with less frequency dependence at f>10 GHz, which results with a solid metal ground plane overlay over the lossy silicon substrate.

Curve 612 shows the middle characteristic impedance with less frequency dependence at f>10 GHz of this invention, which results with the slotted metal ground plane over the lossy silicon substrate.

FIG. 6b shows a plot of attenuation loss vs. frequency. Curve 623 shows the highest attenuation loss up to 10 GHz and the lowest loss at frequencies>18 GHz, which results with a solid metal ground plane overlay over the lossy silicon substrate. Curve 621 shows the lowest loss at frequencies<8 GHz and the highest loss at frequencies greater than or equal to 11 GHz, which results with no metal ground plane over the lossy silicon substrate.

Curve 622 shows the attenuation loss of this invention, which results with the slotted metal ground plane over the lossy silicon substrate. The loss is in the middle of the two previous cases for frequencies less than or equal to 8 GHz and for frequencies greater than or equal to 18 GHz. The loss is the lowest for frequencies 8 to 16 GHz.

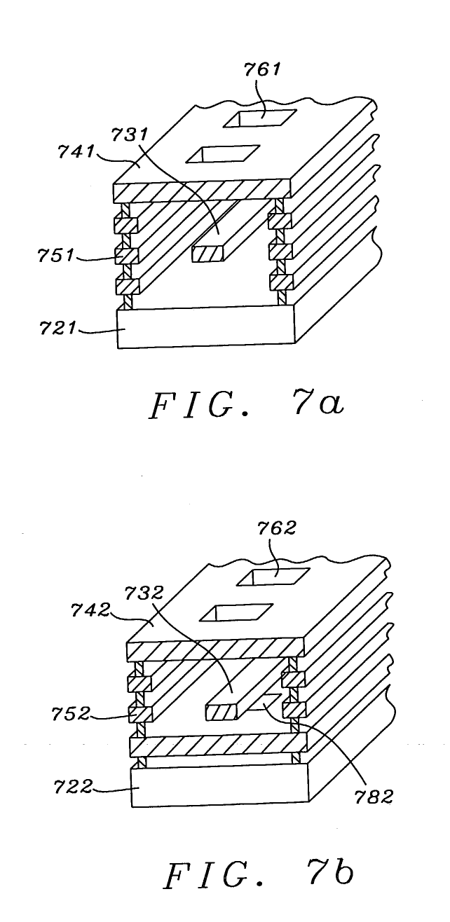

FIG. 7a shows a second embodiment of this invention. In this figure, the main conductor 731 is between the lossy silicon substrate 721 and a layer of metal 741 with openings 761. This structure in FIG. 7a is different than the first embodiment shown in FIGS. 4a, 4b, and 4c, where the metal layer with slots or openings is underneath the main conductor. The structure of FIG. 7a also provides the ability to change the inductance, resistance, transconductance and capacitance (L, R, G, and C) of the transmission line. For example, by changing the number of slots 761, changing the size and position of the slots 761 in the metal 741, the transmission line network made up of the equivalent L, R, G and C is easily changed. By changing L, R, G and C, the characteristic impedance, Zc, and the attenuation loss can be manipulated without the complex integrated circuit fabrication changes necessary to change line width, thickness of metal lines, and/or thickness of the dielectric layer. FIG. 7b shows a third embodiment of this invention. In this figure, the main conductor 732 is embedded between two ground planes 772 and 742 with slotted openings 782 and 762 respectively. The metal ground planes can be connected to the lossy silicon substrate 722. The structure of FIG. 7b also provides the ability to change the inductance, resistance, transconductance and capacitance (L, R, G, and C) of the transmission line. For example, by changing the number of slots 762 and 782, changing the size and position of the slots 762 in the metal 742 and 782 in the metal 772, the transmission line network made up of the equivalent L, R, G and C is easily changed. By changing L, R, G and C, the characteristic impedance, Zc, and the attenuation loss can be manipulated without the complex integrated circuit fabrication changes necessary to change line width, thickness of metal lines, and/or thickness of the dielectric layer.

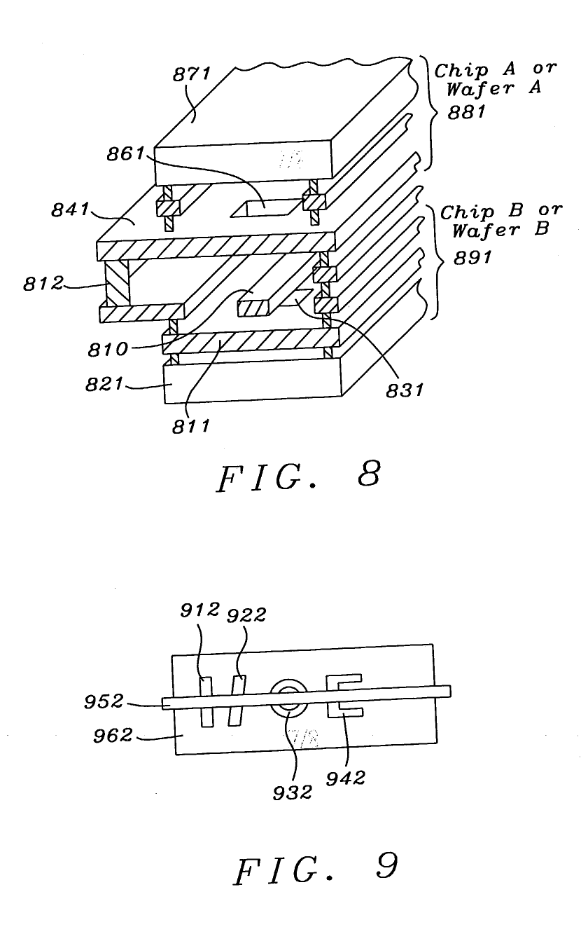

FIG. 8 shows a fourth embodiment of this invention. As in FIG. 7b, this figure has its main conductor 810 embedded between metal ground planes 811 and 841 with slotted openings 831 and 861 respectively. However, the difference from the third embodiment is now the two ground planes are attached to two different wafers or chips A 881 and B 891. The slotted metal ground plane 841 is connected to lossy silicon substrate 871 through standard vias and contacts, while the slotted metal ground plane 811 is connected to lossy silicon substrate 821 through other standard vias and contacts. The two wafers or chips, A and B, are connected through“super vias” 812. The super vias can be formed by ball bumps in flip chip technology, copper vias in wafer to wafer bonding technology, or any other methods. The structure in FIG. 8 is symmetric. The structure of FIG. 8 provides the ability to change the inductance, resistance, transconductance and capacitance (L, R, G, and C) of the transmission line. For example, by changing the number of slots 831 and 861, changing the size and position of the slots 831, 861, the transmission line network made up of the equivalent L, R, G and C is easily changed. By changing L, R, G and C, the characteristic impedance, Zc, and the attenuation loss can be manipulated without the complex integrated circuit fabrication changes necessary to change line width, thickness of metal lines, and/or thickness of the dielectric layer.

FIG. 9 shows a top view looking down on the main conductor 952 over a metal ground plane 962. In addition, various shapes of holes or slots are shown. The slotted rectangle 912 is the preferred shape. However, other angular 922, circular 932 and curved 942 slots are possible.

The advantage of this invention includes the ability to modify the geometry of the slots or absence of metal over the lossy silicon substrate and the geometry of the main conductor. By simply including the slots in the ground plane(s) during the design/mask layout (independent of integrated circuit, IC lithography), we can change the inductance L, resistance R, transconductance G, and capacitance C of the transmission line. With the flexibility to change the L, R, G, and C values of the distributed network model of the integrated circuit transmission line, the characteristic impedance Zc and the attenuation loss can be manipulated without changing linewidth, thickness of the metal lines and/or the thickness of the dielectric layer. Changing linewidth, thickness of the metal lines and/or the thickness of the dielectric layer require complex integrated circuit fabrication process technology development. This invention allows the optimization of transmission line characteristic impedance and attenuation without complex process technology development.

The principle theory is the same, since it does not matter where the ground plane(s) with slots is placed with respect to the transmission line (below the transmission in FIGS. 4a, 4b, and 4c, above the transmission line in FIG. 7a, and both below and above the transmission line in FIG. 7b). The slots in the ground plane will provide the designer an extra means to tune R, L, C and G to obtain the desired Zc and the desired attenuation, α.

The same principle extends to the latest technology, 3-dimensional, 3-D interconnects or wafer-to-wafer bonding. FIG. 8 shows a 3-D interconnection between 2 wafers through a“super via”. We can manipulate Zc and the attenuation, α, of a transmission line in wafer A by having a ground plane with slots in wafer B. Even though it is best to have slots drawn perpendicular (912) to the direction of current flow in the transmission line, other layouts such as shown in 922, 932, and 942 or their variations can induce changes in Zc and the attenuation, α, of this transmission line. They all have components perpendicular to the transmission line.

While the invention has been described in terms of the preferred embodiments, those skilled in the art will recognize that various changes in form and details may be made without departing from the spirit and scope of the invention.

What is claimed is:

1. A low loss transmission line comprising:
an electrical conductor, which traverses the center of said transmission line;
an isolation material or insulator under said electrical conductor; and
a metal ground plane with periodic slots cut out of the metal, which is under said insulator.

2. The low loss transmission line of claim 1 further comprising:
an input port connected to said electrical conductor; and
an output port connected to said electrical conductor.

3. The low loss transmission line of claim 1 further comprising:
a lossy silicon substrate.

4. The low loss transmission line of claim 1 wherein said electrical conductor carries an electrical signal in a direction perpendicular to said slot cutouts.

5. The low loss transmission line of claim 1 wherein said slot cut-outs can be at any angle, shape or curvature.

6. The low loss transmission line of claim 1 wherein said slot cut-outs are optimally effective when they are parallel with the direction of a magnetic field.

7. The low loss transmission line of claim 1 wherein said slot cut-outs have magnetic, H fields looping through said silicon substrate.

8. The low loss transmission line of claim 1 wherein said slot cutouts have electric, [symbol] , fields looping through said silicon substrate.

9. The low loss transmission line of claim 1 wherein said metal ground plane areas of said transmission line have said [symbol] fields terminating at said ground plane.

10. The low loss transmission line of claim 1 wherein said metal ground plane areas of said transmission line have said [symbol] fields terminating at said ground plane.

11. A method of transmitting high frequency electrical signals via a transmission line with low loss comprising the steps of:
providing an electrical conductor, which goes down the center of said transmission line, providing an isolation material or insulator under said electrical conductor; and
providing a metal ground plane with periodic slots cut out of the metal, which is under said insulator.

12. The method of transmitting high frequency electrical signals via a transmission line with low loss of claim 11 further comprising the steps of:
connecting an input port to said electrical conductor; and
connecting an output port to said electrical conductor.

13. The method of transmitting high frequency electrical signals via a transmission line with low loss of claim 11 further comprising the steps of:
providing a lossy silicon substrate.

14. The method of transmitting high frequency electrical signals via a transmission line with low loss of claim 11 wherein said electrical conductor carries an electrical signal in a direction perpendicular to said slot cutouts.

15. The method of transmitting high frequency electrical signals via a transmission line with low loss of claim 11 wherein said slot cutouts can be at any angle, shape or curvature.

16. The method of transmitting high frequency electrical signals via a transmission line with low loss of claim 11 wherein said slot cutouts are optimally effective when they are parallel with the direction of a magnetic field.

17. The method of transmitting high frequency electrical signals via a transmission line with low loss of claim 11 wherein said slot cutouts have magnetic, [symbol] , fields looping through said silicon substrate.

18. The method of transmitting high frequency electrical signals via a transmission line with low loss of claim 11 wherein said slot cutouts have electric fields, [symbol] , looping through said silicon substrate.

19. The method of transmitting high frequency electrical signals via a transmission line with low loss of claim 11 wherein said metal ground plane areas of said transmission line have said [symbol] fields terminating at said ground plane.

20. The method of transmitting high frequency electrical signals via a transmission line with low loss of claim 11 wherein said metal ground plane areas of said transmission line have said [symbol] fields terminating at said ground plane.

21. The method of transmitting high frequency electrical signals via a transmission line with low loss of claim 11 wherein said transmission lines behave as inductor, resistor, transconductance, and capacitor networks when operating at high frequency.

22. The method of transmitting high frequency electrical signals via a transmission line with low loss of claim 11 wherein said networks contain be modeled as a series connection of an inductor and a resistor coupled with a parallel connection of a transconductance and a capacitor.

23. A low loss transmission line comprising:
an electrical conductor which traverse the center of said transmission line;
a first isolation layer or insulator which is under said electrical conductor;
a second isolation layer or insulator which is above said electrical conductor;
a metal ground plane with periodic slots cut out of the metal, which is above said second isolation layer or insulator; and
a lossy silicon substrate which is below said first isolation layer or insulator.

24. The low loss transmission line of claim 29 wherein said slot cut-outs can be at any angle, shape or curvature.

25. The low loss transmission line of claim 29 wherein said slot cut-outs are optimally effective when they are parallel with the direction of a magnetic field.

26. A low loss transmission line comprising:
an electrical conductor which traverse the center of said transmission line;
a first isolation layer or insulator which is under said electrical conductor;
a second isolation layer or insulator which is above said electrical conductor;
a first metal ground plane with periodic slots cut out of the metal, which is under said first isolation layer or insulator;
a second metal ground plane with periodic slots cut out of the metal, which is above said second isolation layer or insulator; and
a lossy silicon substrate which is below said first metal ground plane.

27. The low loss transmission line of claim 26 wherein said slot cut-outs can be at any angle, shape or curvature.

28. The low loss transmission line of claim 26 wherein said slot cut-outs are optimally effective when they are parallel with the direction of a magnetic field.

29. A low loss transmission line comprising:
an electrical conductor which traverse the center of said transmission line;
a first isolation layer or insulator which is under said electrical conductor;
a second isolation layer or insulator which is above said electrical conductor;
a first metal ground plane with periodic slots cut out of the metal, which is under said first isolation layer or insulator;
a second metal ground plane with periodic slots cut out of the metal, which is above said second isolation layer or insulator;
a first lossy silicon substrate which is below said first metal ground plane; and
a second lossy silicon substrate which is above said second metal ground plane.

30. The low loss transmission line of claim 29 wherein said slot cut-outs can be at any angle, shape or curvature.

31. The low loss transmission line of claim 29 wherein said slot cut-outs are optimally effective when they are parallel with the direction of a magnetic field.

32. A method of producing an integrated transmission line comprising the step of:
placing a ground plane with slots below a transmission line.

33. A method of producing an integrated transmission line comprising the step of:
placing a ground plane with slots above a transmission line.

34. A method of producing an integrated transmission line comprising the step of:
placing a ground plane with slots above and below a transmission line.

35. A method of producing an integrated transmission line comprising the steps of:
placing a ground plane with slots in a first wafer,
placing a ground plane with slots in a second wafer,
placing a transmission line in said second wafer,
placing a super via between said first wafer and said second wafer,
bonding said first wafer to said second wafer.

36. A method of producing an integrated transmission line comprising the steps of:
placing a ground plane with slots in a first wafer,
placing a ground plane with slots in a second wafer,
placing a transmission line in said first wafer,
placing a super via between said first wafer and said second wafer,
bonding said first wafer to said second wafer
